(19) United States
(12) Patent Application Publication
(10) Pub. No.: US 2022/0121124 A1
(43) Pub. Date: Apr. 21, 2022

(54) FLOW RESTRICTION, FLOW RESTRICTION ASSEMBLY AND LITHOGRAPHIC APPARATUS

(71) Applicant: ASML NETHERLANDS B.V., 5500 AH. Veldhoven (NL)

(72) Inventors: Bas Bastiaan Cornelis Gijsbertus VAN ELTEN, Waalre (NL); Philippe Jacqueline Johannes Hubertus Anthonius HABETS, Maastricht (NL); Remco VAN DE MEERENDONK, 's-Hertogenbosch (NL)

(73) Assignee: ASML NETHERLANDS B.V., Veldhoven (NL)

(21) Appl. No.: 17/298,202

(22) PCT Filed: Nov. 19, 2019
(86) PCT No.: PCT/EP2019/081738

§ 371 Date: May 28, 2021

(30) Foreign Application Priority Data
Dec. 6, 2018 (EP) 18210707.8

(51) Int. Cl. G03F 7/20; F15D 1/02; F16L 55/027

(52) U.S. Cl. CPC G03F 7/709; F16L 55/02754; F15D 1/025

(57) ABSTRACT

A flow restriction, a flow restriction assembly and methods for manufacturing the flow restriction and the flow restriction assembly. The flow restriction is for use in a pipe so as to restrict the flow of a fluid and includes a body extending along an axis and that has i) a central portion having an essentially constant cross section, ii) an upstream portion, wherein the cross-sectional area of the upstream portion monotonically increases in a downstream direction along the axis; and iii) a downstream portion, wherein the cross-sectional area of the downstream portion monotonically decreases in the downstream direction. The flow restriction also has a plurality of central portion projections for engaging the inner surface of the pipe, each of which projects from the surface of the central portion in a direction perpendicular to the surface of the central portion by a distance of less than 500 μm.

### CROSS-REFERENCE TO RELATED APPLICATIONS

This application claims priority of EP application 18210707.8 which was filed on 6 Dec. 2018 and which is incorporated herein in its entirety by reference.

### FIELD

The present invention relates to a flow restriction, a flow restriction assembly, a lithographic apparatus, a method for manufacturing the flow restriction and a method for manufacturing the flow restriction assembly.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

Within such a lithographic apparatus, a thermal conditioning fluid (e.g. a liquid such as water) is used to keep the thermal conditions of components of the lithographic apparatus within predetermined specifications. The thermal conditioning fluid is provided to the components of the lithographic apparatus using a thermal conditioning circuit comprising one or more interconnected pipes. These pipes comprise flow restrictions for restricting the flow of thermal conditioning fluid through the pipes, so as to control and set the amount of thermal conditioning.

A conventional flow restriction comprises a small hole in a plate that is arranged in a pipe. Such a flow restriction creates a pressure drop by inducing a turbulent separated flow of thermal conditioning fluid. The resulting turbulence results in so-called flow-induced vibrations (FIV). Such FIV may propagate to and affect vibration sensitive components of the lithographic apparatus, for example optical components used to project the pattern of the patterning device onto the substrate. This can lead to focus and overlay errors in the pattern projected onto the substrate.

Flow restrictions that suppress FIV, or low FIV flow restrictions, include flow restrictions comprising a small diameter channel with a very gradual decrease in diameter upstream of the channel and a very gradual increase in diameter downstream of the channel. Such flow restrictions are difficult to manufacture, require a lot of space in the pipe and are easily blocked by contaminant particles that might be present in the thermal conditioning fluid.

### SUMMARY

It is desirable, for example, to provide a flow restriction that suppressed flow induced vibrations and is compact, easy to manufacture, and less susceptible to being blocked by contaminant particles.

According to an aspect of the invention, there is provided a flow restriction for being arranged in a pipe so as to restrict the flow of a fluid in the pipe. The flow restriction comprises a body extending along an axis. The body comprises a centre portion having a constant cross section along the axis, an upstream portion connected to an upstream side of the centre portion along the axis, wherein the cross-sectional area of the upstream portion monotonically increases in a downstream direction along the axis, and a downstream portion connected to a downstream side of the centre portion, wherein the cross-sectional area of the downstream portion monotonically decreases in the downstream direction. The flow restriction further comprises a plurality of centre portion projections for engaging the inner surface of a pipe, wherein each centre portion projection projects from the surface of the centre portion in a direction perpendicular to the surface of the centre portion by a distance of less than 500 μm.

According to a further aspect of the invention, there is provided a flow restriction assembly comprising the flow restriction and a pipe, wherein the pipe comprises an inner pipe surface, the body of the flow restriction is concentrically arranged within the pipe, such that the distance between the centre portion of the body and the inner pipe surface is uniform, and each of the centre portion projections of the flow restriction engages the inner pipe surface so as to hold the flow restriction in place with respect to the pipe, and such that the distance between the centre portion of the body and the inner pipe surface is less than 500 μm.

According to a further aspect of the invention, there is provided a lithographic apparatus comprising the flow restriction assembly.

According to a further aspect of the invention, there is provided a method of manufacturing the flow restriction. The method comprises machining the body from a single precursor material, providing holes with a diameter equal to the diameter of the centre portion projections in the centre portion, inserting the centre portion projections into the holes, and machining the centre portion projections such that all centre portion projections extend by a uniform distance from the surface of the centre portion.

According to a further aspect of the invention, there is provided a method of manufacturing the flow restriction assembly. The method comprises thermally conditioning the flow restriction and/or the pipe such that the temperature of the pipe is higher than the temperature of the flow restriction, inserting the flow restriction into the pipe, and thermally conditioning the flow restriction and/or the pipe such that the temperatures of the pipe and the flow restriction are equal, such that each of the plurality of centre portion projections of the flow restriction engages the inner surface of the pipe.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 schematically depicts a lithographic apparatus;

FIG. 2a depicts a cross-sectional view of a flow restriction assembly according to an embodiment of the present invention in a plane parallel to a pipe axis;

FIG. 2b schematically depicts a cross-sectional view of the flow restriction assembly in plane A-A shown in FIG. 2a; and

FIG. 2c schematically depicts a cross-sectional view of the flow restriction assembly in plane B-B shown in FIG. 2a.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and extreme ultraviolet (EUV) radiation (e.g. with a wavelength around 13 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

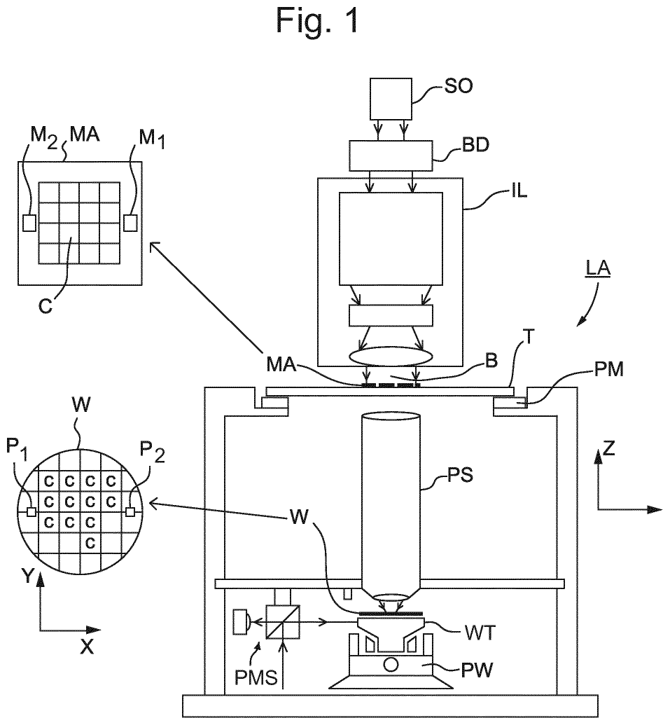

FIG. 1 schematically depicts a lithographic apparatus LA of an embodiment. The lithographic apparatus LA comprises:
optionally, an illumination system (illuminator) IL configured to condition a radiation beam B (e.g. UV radiation or DUV radiation);
a support structure (e.g. a mask table) T constructed to support a patterning device (e.g. a mask) MA and connected to a first positioner PM configured to accurately position the patterning device MA in accordance with certain parameters;
a support table, e.g. a sensor table to support one or more sensors or a substrate table or wafer table WT constructed to hold a substrate (e.g. a resist-coated production substrate) W, connected to a second positioner PW configured to accurately position the surface of the table, for example of a substrate W, in accordance with certain parameters; and
a projection system (e.g. a refractive projection lens system) PS configured to project a pattern imparted to the radiation beam B by patterning device MA onto a target portion C (e.g. comprising part of, one, or more dies) of the substrate W.

In operation, the illuminator IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system”.

The lithographic apparatus LA may be of a type having two or more support tables, e.g., two or more support tables or a combination of one or more support tables and one or more cleaning, sensor or measurement tables. For example, the lithographic apparatus LA is a multi-stage apparatus comprising two or more tables located at the exposure side of the projection system PS, each table comprising and/or holding one or more objects. In an example, one or more of the tables may hold a radiation-sensitive substrate. In an example, one or more of the tables may hold a sensor to measure radiation from the projection system. In an example, the multi-stage apparatus comprises a first table configured to hold a radiation-sensitive substrate (i.e., a support table) and a second table not configured to hold a radiation-sensitive substrate (referred to hereinafter generally, and without limitation, as a measurement, sensor and/or cleaning table). The second table may comprise and/or may hold one or more objects, other than a radiation-sensitive substrate. Such one or more objects may include one or more selected from the following: a sensor to measure radiation from the projection system, one or more alignment marks, and/or a cleaning device (to clean, e.g., the liquid confinement structure).

In operation, the radiation beam B is incident on the pattern (design layout) present on patterning device (e.g., mask) MA, which is held on the support structure (e.g., mask table) T, and is patterned by the patterning device MA. Having traversed the patterning device MA, the radiation beam B passes through the projection system PS, which focuses the beam onto a target portion C of the substrate W. With the aid of the second positioner PW and position sensor PMS (e.g. an interferometric device, linear encoder, 2-D encoder or capacitive sensor), the substrate table WT can be moved accurately, e.g. so as to position different target portions C in the path of the radiation beam B at a focused and aligned position. Similarly, the first positioner PM and another position sensor (which is not explicitly depicted in FIG. 1) can be used to accurately position the patterning device MA with respect to the path of the radiation beam B. Patterning device MA and substrate W may be aligned using patterning device alignment marks M1, M2 and substrate alignment marks P1, P2. Although the substrate alignment marks Pl, P2 as illustrated occupy dedicated target portions C, they may be located in spaces between target portions C (these are known as scribe-lane alignment marks).

The lithographic apparatus LA may further comprise a thermal conditioning system (not shown) for thermally conditioning (e.g. cooling) one or more components of the lithographic apparatus LA. The thermal conditioning system may provide a thermal conditioning fluid (e.g. a liquid such as water) to components of the lithographic apparatus LA via a thermal conditioning circuit. The thermal conditioning circuit may comprise one or more pipes that direct the thermal conditioning fluid to the component of the lithographic apparatus LA that is to be thermally conditioned. The component of the lithographic apparatus LA that is to be thermally conditioned may, for example, be a component of the projection system PS, the support table or a sensor positioned on the support table, the patterning device MA, a component of the illumination system, or the source of the radiation beam B.

Each pipe of the fluid conditioning circuit may provide the thermal conditioning fluid to a respective component of the lithographic apparatus LA. A flow restriction may be provided in each pipe to control or set the flow rate of thermal conditioning fluid to the respective component, and so to control or set the rate of thermal conditioning (e.g. the cooling rate) of the respective component of the lithographic apparatus LA.

Existing flow restrictions may give rise to FIV, which can affect the accuracy of the pattern projected onto the substrate and lead to focus and overlay errors. Existing low FIV flow restrictions may be difficult to fabricate, take a lot of space within a pipe (and so cannot be used in short pipes) and may become clogged by contaminant particles.

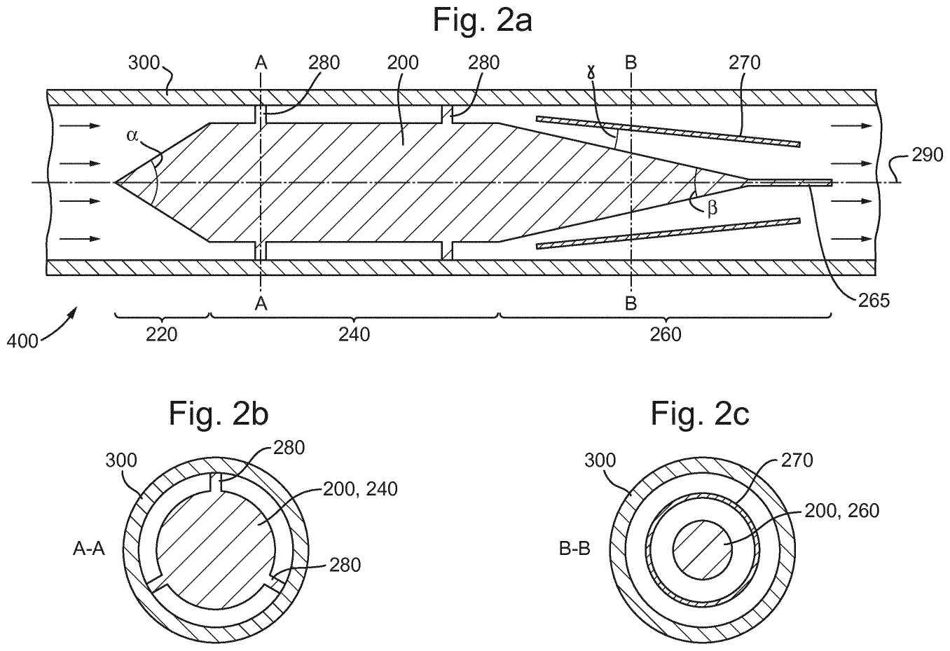

In order to address the problems of existing flow restrictions used in a lithographic apparatus LA, the flow restriction assembly 400 shown in FIG. 2 may be provided. The flow restriction assembly 400 comprises a flow restriction 200 and a pipe 300. The pipe 300 may form part of the lithographic apparatus LA. For example, the pipe 300 may provide the thermal conditioning fluid to the radiation beam source of the lithographic apparatus LA for thermally conditioning the radiation beam source. Alternatively, the pipe 300 may provide the thermal conditioning fluid to the projection system PS of the lithographic apparatus LA for thermally conditioning the projection system PS. Further alternatively, the pipe 300 may provide the thermal conditioning fluid to any other component of the lithographic apparatus LA that is to be thermally conditioned.

The flow restriction 200 restricts the flow of a fluid, such as the thermal conditioning fluid, in the pipe 300. The flow restriction 200 comprises a body having an upstream portion 220, a centre portion 240, and a downstream portion 260. The upstream portion 220 is connected to an upstream (or first) side of the centre portion 240 along an axis 290. The downstream portion 260 is connected to a downstream (or second) side of the centre portion 240 along the axis 290. The flow restriction 200 further comprises a plurality of centre portion projections 280. In the flow restriction assembly 400 shown in FIG. 2, each of the centre portion projections 280 engages an inner pipe surface of the pipe 300 so as to hold the flow restriction 200 in place with respect to the pipe 300. The body of the flow restriction 200 is concentrically arranged within the pipe 300, such that the distance between the centre portion 240 of the flow restriction 200 and the inner surface of the pipe 300 is uniform.

The centre portion 240 has a constant cross section along the axis 290, such that, at any point along the axis 290, the cross section of the centre portion 240 in the plane perpendicular to the axis 290 is identical. The pipe 300 also has a constant cross section along the axis 290. In the flow restriction assembly 400, the body of the flow restriction 200 is arranged concentrically in the pipe 300, such that the distance between the inner surface of the pipe 300 and the centre portion 240 of the flow restriction 200 is uniform.

The flow restriction 200 further comprises a plurality of centre portion projections 280. Each centre portion projection 280 projects from the surface of the centre portion 240 in a direction perpendicular to the surface of the centre portion 240 by a distance of less than 500 μm. In the flow restriction assembly 400 shown in FIG. 2, the length of the centre portion projections 280 determines the size of the uniform gap between the centre portion 240 and the pipe 300. The distance between the centre portion 240 and the inner surface of the pipe 300 is thus less than 500 μm. The flow restriction 200 is thus suitable for creating a small gap with a dimension of less than 500 μm between the inner surface of the pipe 300 and the flow restriction 200.

Due to the small dimension (of less than 500 μm) of the gap, a fluid flowing through the gap experiences high viscous pressure losses arising from the high fluid flow velocity gradients in the gap (as opposed to the pressure losses due to turbulent separated flow of conventional flow restrictions). The flow restriction 200 thus allows creation of the pressure drop required in the pipe 300 to control thermal conditioning of the lithographic apparatus LA without relying on turbulent separated flow. FIV can thus be avoided or at least reduced compared to flow restrictions that achieve pressure losses due to turbulent separated flow. At the same time, the flow restriction 200 is not susceptible to being blocked by a single contaminant particle. The flow restriction 200 is also easier to introduce into the pipe 300 than conventional low FIV flow restrictions, as the contact area between the pipe 300 and the flow restriction 200 is small compared to conventional low FIV flow restrictions.

The pressure drop created by the flow restriction 200 is mostly dependent on the length of the centre portion projections 280 in a direction perpendicular to the axis 290 and on the length of the centre portion 240 in a direction along the axis 290. Reducing the length of the centre portion projections 280 allows a corresponding decrease in length of the centre portion 240 for any given desired pressure drop. For use in the lithographic apparatus LA, the flow restriction desirably creates a pressure drop of several hundreds of kPa. Providing centre portion projections 280 with a length of less than 500 μm ensures that such a pressure drop can be achieved while keeping the centre portion 280 compact. The centre portion may, for example, have a length in the range from 1 cm to 100 cm, and in particular from 4 cm to 15 cm, to achieve such pressure drops. Compared to conventional low FIV flow restrictions, which are about twice as long to achieve the same pressure drops, the flow restriction 200 is thus compact.

A surprising effect of providing centre portion projections 280 with a length of less than 500 μm, and of the high viscous forces acting on a fluid flowing through a gap generated by the centre portion projections 280, is that, in use, the flow restriction 200 exhibits high silencing properties. The flow restriction 200 thus not only gives rise to low FIV, it also dampens vibrations that travel along the pipe 300. As such, vibrations that originate, for example, from a pump positioned upstream of the flow restriction assembly 400 may be dampened by the flow restriction assembly 400 and at least reduced such that they do not affect a vibration sensitive component positioned downstream of the flow restriction assembly 400. Such silencing properties are both due to resistive silencing arising from to the high shear stresses stemming from high velocity gradients in the small gap between the flow restriction 200 and the pipe 300 (which dissipate the acoustic energy of vibrations traveling along the pipe 300), and due to reactive silencing arising from the reflection of waves created by an admittance mismatch due to minute changes in cross sectional area due to such vibrations.

Preferably, each centre portion projection 280 projects from the surface of the centre portion 240 in a direction perpendicular to the surface of the centre portion 240 by a distance of less than 100 μm, further preferably by a distance of less than 50 μm. This further increases the fluid flow velocity gradients in the gap between the flow restriction 200 and the pipe 300, thus further increasing the viscous pressure losses created by the flow restriction. The flow restriction 200 may thus be made shorter in a direction along the axis 290 to achieve a given pressure drop, such that the flow restriction 200 may be more compact and can be provided in a shorter pipe. Reducing the length of the projections 280 to less than 100 μm, in particular less than 50 μm, also significantly improves the silencing properties of the flow restriction 200.

In an embodiment, each centre portion projection 280 projects from the surface of the centre portion 240 in a direction perpendicular to the surface of the centre portion 240 by a distance of more than 10 μm. Providing centre portion projections 280 with a length of more than 10 μm ensures that the centre portion projections 280 can be machined to an acceptable margin of error using simple fabrication methods (such as fabrication methods allowing, for example, for an accuracy of up to 1 μm). Reducing the length of the centre portion projections 280 further would increase the cost and complexity of manufacturing the flow restriction 200.

In the flow restriction assembly 400 of FIG. 2, the body (and so each of the upstream portion 220, the centre portion 240 and the downstream portion 260) has a cross sectional area in the plane perpendicular to the axis 290 which is shaped geometrically similar to (but smaller than) the cross sectional area of the inner space of the pipe 300. The pipe 300 may have an inner dimension in a direction perpendicular to the axis 290, for example, of more than 1 cm. At any point along the axis 290, the cross section of the body in the plane perpendicular to the axis 290 may be geometrically similar, so identical in shape but not necessarily identical in size. The surface of the body may be continuous in the downstream direction, such that no sharp edges act on the fluid flowing around the flow restriction 200 in the pipe 300. The cross sectional area of the flow restriction 200 may thus be shaped to correspond to any available pipe 300. For example, the flow restriction 200 may be rotationally symmetric with respect to the axis 290. The cross section of the body may, for example, be a regular polygon or a circle. The cross section of the body may be similar to the cross section of conventionally used pipes, such as round pipes, triangular pipes, square pipes, and others. The flow restriction 200 may thus be arranged in conventionally available pipes.

In the embodiment shown in FIGS. 2b and 2c, the body and the pipe 300 are cylindrically symmetric about the axis 290. The cross section of the body is a circle. The centre portion 240 comprises a cylinder. Each of the plurality of centre portion projections 280 projects in a direction perpendicular to the axis 290 and intersecting the axis 290. The radius of the cylinder may be less than 500 μm shorter than the radius of the inner surface of a conventional round pipe 300. The radius of the inner surface of the pipe 300 may, for example, be more than 0.5 cm. The centre portion 240 may have a length along the axis 290 in the range from 1 cm to 100 cm, in particular 4 cm to 15 cm. Such a length, in combination with centre portion projections 280 having a length of less than 500 μm, in particular less than 100 μm, allows the flow restriction 200 to create pressure drops of several hundreds of kPa, as required in the thermal conditioning circuit of the lithographic apparatus LA.

The cross sectional area of the upstream portion 220 monotonically increases in the downstream direction along the axis 290. The upstream portion 220 may be convex. The upstream portion 220 may, for example, monotonically increase in the downstream direction from a point (at the upstream end of the upstream portion 220) to a cross section that is identical to the cross section of the centre portion 240. The exact shape of the upstream portion 220 has been found not to be critical to the performance of the flow restriction 200. The upstream portion 200 may thus have any shape that monotonically increases in the downstream direction. As shown in FIG. 2, the upstream portion 220 may comprise a cone, for example. The cone may have a cone angle α in the range from 45° to 90°. The inventors have found that an upstream portion 220 with a cone angle α of less than 90° does not create unacceptable levels of FIV. A cone angle α of more than 45° ensures that the upstream portion 220 is compact, such that the flow restriction 220 is compact and can be arranged in the pipe 300 even if the pipe 300 is short. The cone angle α may, however, also be less than 45° or more than 90°. Alternatively, the upstream portion 220 may not comprise a cone, and instead comprise, for example, a hemisphere, paraboloid, or any other shape that monotonically increases in the downstream direction. The impact of the upstream portion 220 on FIV created by the flow restriction 200 is small compared to the impact of other portions of the flow restriction 200, such that the exact shape of the upstream portion 220 is of comparably less importance when considering FIV. Preferably, the upstream portion 220 has a length along the axis 290 which is shorter than the maximum dimension of the upstream portion 220 in a direction perpendicular to the axis 290, such that the flow restriction 200 is compact.

The cross-sectional area of the downstream portion 260 monotonically decreases in the downstream direction. The cross section of the downstream portion 260 may decrease gradually, for example decrease at a maximum angle in the range from 1° to 8°, preferably in the range from 1° to 5°, with respect to the axis 290, at any point along the axis 290. Such a maximum angle reduces the risk of turbulent flow separation as the fluid flow expands in cross section in the downstream portion 260.

As shown in FIG. 2, the downstream portion 260 may comprise a cone. The cone angle β of the cone may be in the range from 2° to 15°, preferably in the range from 2° to 10°. The inventors have found that a cone angle β of less than 15° reduces the risk of turbulent flow separation and thus reduces FIV. A cone angle β of more than 2° allows the downstream portion 260 to be made compact in comparison to smaller cone angles, such that the flow restriction 220 is compact and can be arranged in the pipe 300 even if the pipe 300 is short.

In one embodiment, the cone angle β is in the range from 2° to 5°. For such a cone angle β, the expansion of the fluid flow around the downstream portion 260 is gradual enough to suppress turbulent flow separation and FIV without requiring the provision of further elements (such as a flow splitting element 270). This makes assembly of the fluid flow assembly 400 simple.

Each of the plurality of centre portion projections 280 may have a constant cross section in a plane perpendicular to the direction in which the respective centre portion projection 280 projects from the surface of the centre portion 240. This makes fabrication of the centre portion projections 280 simple, and keeps the contact area between the flow restriction 200 and the pipe 300 small, making fabrication of the flow restriction assembly 400 simple compared to conventional low FIV flow restrictions. Each of the plurality of centre portion projections 280 may comprise a cylinder that extends along a surface perpendicular to the centre portion 240. A centre portion projection 280 made of such a cylinder is simple to fabricate compared to other shapes. Each centre portion projection 280 may be identical. The diameter of each centre portion projection 280 may be in the range from 0.5 mm to 3 mm. A compressive force may act on each of the centre portion projections 280 when the flow restriction 200 is inserted in the pipe 300, so as to keep the flow restriction 200 in place in the pipe 300.

The plurality of centre portion projections 280 may comprise two sets of centre portion projections 280, wherein each set is arranged in a different plane that is perpendicular to the axis 290 (e.g. one set at an upstream side of the centre portion 240 and another set at the downstream side of the centre portion 240. Preferably, each set of centre portion projections 280 may consist of three centre portion projections 280. Three centre portion projections 280 are the minimum number of centre portion projections 280 that is required to hold the flow restriction 200 in place. Providing fewer centre portion projections 280 makes assembly of the flow restriction assembly 400 easier and reduces the impact of the centre portion projections 280 on FIV. Alternatively, four or more centre portion projections 280 may be provided in each set of centre portion projections 280. As shown in FIG. 2b, the centre portion projections 280 may be arranged at equal intervals around the surface of the centre portion 240, for an equal load distribution at each centre portion projection 280.

In one embodiment, the downstream portion 260 further comprises a cusped edge 265. The cusped edge 265 is provided on the downstream side of the downstream portion 260. The cusped edge 265 directs a fluid flowing along the surface of the cusped edge 265 in a direction parallel to the axis 290. This ensures that the fluid flow on one side of the downstream portion 260 (e.g. above the downstream portion 260 in FIG. 2) does not cross over with the fluid flow on an opposite side of the downstream portion 260 (e.g. below the downstream portion 260 in FIG. 2) at a point directly downstream of the downstream portion 260. The cusped edge may thus be used to achieve a Kutta-optimized outlet, such that a wake of the fluid flow downstream of the flow restriction 200 is minimized This reduces turbulence downstream of the flow restriction 200, and thus further reduces FIV. The maximum extent in a direction perpendicular to the axis 290 of the cusped edge 265 at its downstream end may be in the range from 0.5 mm to 3 mm. A thickness of less than 3 mm reduces the risk of turbulent flow separation at the downstream end of the cusped edge 265, while a thickness of more than 0.5 mm ensures that fabrication of the cusped edge 265 is simple and that the cusped edge 265 does not break easily.

In an embodiment, the flow restriction 200 further comprises a flow splitting element 270. The flow splitting element 270 splits the space surrounding the downstream portion 260 (and so, in use, the flow of fluid flowing through the pipe 300) into a radially inner space (in use, a radially inner flow) between the downstream portion 260 and the flow splitting element 270, and a radially outer space (in use, a radially outer flow). In the flow restriction assembly 400, the radially outer space is positioned between the flow splitting element 270 and the pipe 300. As shown in FIG. 2c, the flow splitting element 270 entirely surrounds the downstream portion 260 of the body in a plane perpendicular to the axis 290. The flow splitting element 270 is spaced apart from the downstream portion 220 in a direction perpendicular to the axis 290 such that the distance between the flow splitting element 270 and the downstream portion 260 monotonically increases in the downstream direction. The downstream end of the flow splitting element 270 is located closer to the axis 290 than the upstream end of the flow splitting element 270. In the flow restriction assembly 400, the distance between the pipe 300 and the flow splitting element 270 monotonically increases in the downstream direction. The flow splitting element 270 may thus decrease the effective expansion angle γ experienced by the fluid flowing along the downstream portion 260, compared to the angle β/2 experienced by the fluid in the absence of the flow splitting element 270. This reduces the risk of turbulent flow separation and resulting FIV. When the flow restriction 200 comprises the flow splitting element 270, the cone angle β may thus be increased compared to a situation in which the flow restriction 200 does not comprise the flow splitting element 270, while maintaining FIV suppression. For example, in the presence of the flow splitting element 270, the cone angle β may be in the range from 5° to 15° while reducing the risk of turbulent flow separation. Such a comparably larger cone angle β allows the downstream portion 240, and so the flow restriction 200, to be made more compact.

The flow splitting element 270 may have a thickness in the range from 0.3 mm to 2 mm. The thickness of the flow splitting element 270 may be constant. Such a thickness reduces the risk of the flow splitting element 270 itself creating turbulent flow conditions compared to larger thicknesses, while making the flow splitting element 270 stable and easy to fabricate compared to smaller thicknesses. The flow splitting element 270 may, for example, comprise a truncated hollow cone, as shown in FIG. 2. The truncated hollow cone is concentrically arranged around the downstream portion 260. The truncated hollow cone may have a cone angle in the range from 0.3 to 0.7 times the cone angle β of the cone of the downstream portion, preferably from 0.4 to 0.6 times the cone angle β or about half of the cone angle β. This allows the fluid flow to be split relatively evenly between a flow that is radially within the flow splitting element 270 and a flow that is radially outside the flow splitting element 270. The effective angle of expansion experienced by either of these flows can thus be reduced effectively.

The flow splitting element 270 may be shorter than the downstream portion 260 in a direction along the axis 290. The flow splitting element 270 may thus be arranged around the downstream portion 260 such that the overall length of the flow restriction 200 along the axis 290 is not affected. The flow restriction 200 thus remains compact in the presence of the flow splitting element 270.

The flow splitting element 270 may comprise a plurality of flow splitting element projections (not shown) for engaging the inner surface of the pipe 300. The shape, size and arrangement of the flow splitting element projections may be identical to the shape, size and arrangement of the centre portion projections 280. The distance between the axis 290 and the end surfaces of the flow splitting element projections is equal to the distance between the axis 290 and the end surfaces of the centre portion projections 280, so as to be equal to the distance between the axis 290 and the inner surface of the pipe 300. The flow splitting element projections may thus engage the pipe 300 so as to hold the flow splitting element 270 in place in relation to the downstream portion 260. Alternatively or additionally, the flow splitting element 270 may be fixedly connected to the body of the flow restriction 200, for example to the downstream portion 260 of the flow restriction 200. This ensures that the positional relation between the body and the flow splitting element 270 is fixed, such that the fluid flow around the body can be split reliably between the radially inner flow and the radially outer flow by the flow splitting element 270.

The flow restriction 200 (including the flow splitting element 270) may be made from a single precursor material. This makes fabrication of the flow restriction 200 simple. For example, the flow restriction 200 may be made entirely of a rigid polymer, such as PTFE, PFA, PEEK, or any other rigid polymer. Use of a polymer for the flow restriction 200 avoids galvanic corrosion in the flow restriction assembly 400, when the pipe 300 comprises a metal. Alternatively, the flow restriction 200 may be made from the same material, for example the same metal (such as stainless steel), as the pipe 300. This also prevents galvanic corrosion which might arise if the flow restriction 200 is made from a different metal than the pipe 300.

A method of manufacturing the flow restriction 200 comprises machining the body of the flow restriction 200 (so the upstream portion 220, the centre portion 240, and the downstream portion 260) from a single precursor material. This makes fabrication of the body simpler than machining the portions of the body separately and connecting the portions thereafter. The body machined in such a way may comprise the cusped edge 265. The method may further comprise providing holes with a diameter equal to the diameter of the centre portion projections 280 in the centre portion 240, for example by drilling holes in the centre portion 240. The centre portion projections 280 may then be inserted into the holes. The centre portion projections may, before insertion, have a length larger than half the thickness of the centre portion 240. The centre portion projections 280 may be held in the holes by an interference fit. Alternatively, an adhesive could be used to fix the centre portion projections 280 in the holes. In a final step, the centre portion projections 280 may be machined such that all centre portion projections 280 extend from the surface of the centre portion 240 by a uniform distance, in particular by less than 500 μm. The final machining step preferably achieves a margin of error of less than 1 μm. The method may further comprise fabricating the flow splitting element 270 in a separate method step.

Alternatively, the entire flow restriction 200 may be fabricated by additive manufacturing, such as 3D printing. This may make fabrication even simpler, and is especially suitable for fabricating flow restrictions 200 made of a rigid polymer.

A method of manufacturing the flow restriction assembly 400 comprises thermally conditioning the flow restriction 200 and/or the pipe 300 such that the temperature of the pipe 300 is higher than the temperature of the flow restriction 200. For example, the pipe 300 may be heated to a temperature well above room temperature, and/or the flow restriction 200 may be cooled (e.g. using liquid nitrogen) to a temperature well below room temperature. After such thermal conditioning, the inner diameter of the pipe 300 is larger than the maximum lateral dimension of the flow restriction 200 due to thermal expansion of the pipe 300 and/or thermal contraction of the flow restriction 200. The flow restriction 200 may then be inserted into the pipe 300. The method may comprise a final step of thermally conditioning the flow restriction and/or the pipe (e.g. by allowing the flow restriction and the pipe to reach the temperature of a surrounding atmosphere) such that the temperatures of the pipe and the flow restriction are equal. This will lead to thermal contraction of the pipe 300 and/or thermal expansion of the flow restriction 200, such that the plurality of center portion projections 280 of the flow restriction 200 engage the inner surface of the pipe 300.

Alternatively, the flow restriction assembly 400 may be fabricated by press-fitting the flow restriction 200 into the pipe 300, optionally using a lubricant. The flow restriction 200 may be held in the pipe 400 by an interference fit. This method of fabricating the flow restriction assembly 400 may be more suitable for use with flow restrictions 200 (e.g. flow restrictions 200 made of a rigid polymer) that might be damaged by large temperature changes.

Although the present invention has been described in the context of the lithographic apparatus LA, it should be understood that the flow restriction 200 and the flow restriction assembly 400 may be used for restricting the flow of a fluid in other applications, in particular in any applications that benefit from low FIV. This includes any other substrate processing, measurement and testing apparatuses that require register accuracy of components or fabrication means. The flow restriction 200 and flow restriction assembly 400 may, for example, be used in a pipe 300 that is part of a metrology (or inspection) apparatus, which is for measuring parameters of interest of structures on the substrate. Such a metrology apparatus can be used to measure parameters such as critical dimension, overlay between layers on the substrate and asymmetry of a pattern on the substrate.

Although specific reference may be made in this text to the use of a lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains one or multiple processed layers.

The descriptions above are intended to be illustrative, not limiting. Thus, it will be apparent to one skilled in the art that modifications may be made to the invention as described without departing from the scope of the claims set out below.

Clauses:

Clause 1. A flow restriction for being arranged in a pipe so as to restrict the flow of a fluid in the pipe, the flow restriction comprising:
a body extending along an axis, the body comprising:
a centre portion having a constant cross section along the axis; an upstream portion connected to an upstream side of the centre portion along the axis, wherein the cross-sectional area of the upstream portion monotonically increases in a downstream direction along the axis; and a downstream portion connected to a downstream side of the centre portion, wherein the cross-sectional area of the downstream portion monotonically decreases in the downstream direction; and wherein the flow restriction further comprises a plurality of centre portion projections for engaging the inner surface of a pipe, wherein each centre portion projection projects from the surface of the centre portion in a direction perpendicular to the surface of the centre portion by a distance of less than 500 μm.

Clause 2. The flow restriction of clause 1, wherein each centre portion projection projects from the surface of the centre portion in a direction perpendicular to the surface of the centre portion by a distance of more than 10 μm.

Clause 3. The flow restriction of clause 1 or 2, wherein the body is cylindrically symmetric about the axis, the centre portion comprises a cylinder, and each of the plurality of projections projects in a direction perpendicular to the axis.

Clause 4. The flow restriction of clause 3, wherein the downstream portion comprises a cone with a cone angle in the range from 2° to 15°.

Clause 5. The flow restriction of any one of the preceding clauses, wherein the centre portion has a length along the axis in the range from 4 cm to 15 cm.

Clause 6. The flow restriction of any one of the preceding clauses, wherein the downstream portion comprises a cusped edge configured to direct a fluid flowing along the surface of the cusped edge in a direction parallel to the axis.

Clause 7. The flow restriction of clause 6, wherein the cusped edge has, at its downstream end, a maximum extent in a direction perpendicular to the axis in the range from 0.5 mm to 3 mm.

Clause 8. The flow restriction of any preceding clauses, further comprising a flow splitting element that is configured to entirely surround the downstream portion of the body in a plane perpendicular to the axis, wherein the flow splitting element is configured to be spaced apart from the downstream portion in a direction perpendicular to the axis such that the distance between the flow splitting element and the downstream portion monotonically increases in the downstream direction.

Clause 9. The flow restriction of clause 8, wherein the flow splitting element has a thickness in the range from 0.3 mm to 2 mm.

Clause 10. The flow restriction of clause 8 or 9, wherein the flow splitting element comprises a truncated hollow cone that is concentrically arranged around the downstream portion.

Clause 11. The flow restriction of clause 10, wherein the downstream portion comprises a cone and wherein the truncated hollow cone has a cone angle in the range from 0.3 to 0.7 times the cone angle of the cone of the downstream portion.

Clause 12. The flow restriction of any one of clauses 8 to 11, wherein the flow splitting element is shorter than the downstream portion in a direction along the axis.

Clause 13. The flow restriction of any one of clauses 8 to 12, wherein the flow splitting element comprises a plurality of flow splitting element projections for engaging the inner surface of a pipe, wherein the distance between the axis and the end surfaces of the flow splitting element projections is equal to the distance between the axis and the end surfaces of the centre portion projections.

Clause 14. The flow restriction of any one of clauses 8 to 13, wherein the flow splitting element is fixedly connected to the body.

Clause 15. The flow restriction of any one of the preceding clauses, wherein the flow restriction is made entirely of a rigid polymer.

Clause 16. A flow restriction assembly comprising the flow restriction of any one of the preceding clauses and a pipe, wherein
the pipe comprises an inner pipe surface;
the body of the flow restriction is concentrically arranged within the pipe, such that the distance between the centre portion of the body and the inner pipe surface is uniform; and each of the centre portion projections of the flow restriction engages the inner pipe surface so as to hold the flow restriction in place with respect to the pipe, and such that the distance between the centre portion of the body and the inner pipe surface is less than 500 μm.

Clause 17. The flow restriction assembly of clause 16, wherein the pipe and the body of the flow restriction are cylindrically symmetric.

Clause 18. The flow restriction assembly of clause 16 or 17, wherein the flow restriction is the flow restriction of any one of clauses 8 to 14, and wherein the flow splitting element of the flow restriction entirely surrounds the downstream portion of the flow restriction in a plane perpendicular to the axis, and the flow splitting element is spaced apart from the downstream portion in a direction perpendicular to the axis such that the distance between the splitter plate and the downstream portion monotonically increases in the downstream direction.

Clause 19. The flow restriction assembly of any one of clauses 16 to 18, wherein the pipe and the flow restriction are made of the same material.

Clause 20. A lithographic apparatus comprising the flow restriction assembly of any one of clauses 16 to 19.

Clause 21. The lithographic apparatus of clause 20, further comprising a radiation beam source; wherein the pipe of the flow restriction assembly is configured to provide a liquid to the radiation beam source for thermally conditioning the radiation beam source.

Clause 22. The lithographic apparatus of clause 20, further comprising a projection system for projecting a radiation beam onto a substrate; wherein the pipe is configured to provide a liquid to the projection system for thermally conditioning the projection system.

Clause 23. A method of manufacturing the flow restriction of any one of clauses 1 to 15, the method comprising: machining the body from a single precursor material; providing holes with a diameter equal to the diameter of the centre portion projections in the centre portion; inserting the centre portion projections into the holes; machining the centre portion projections such that all centre portion projections extend by a uniform distance from the surface of the centre portion.

Clause 24. A method of manufacturing the flow restriction assembly of any one of clauses 16 to 19, the method comprising thermally conditioning the flow restriction and/or the pipe such that the temperature of the pipe is higher than the temperature of the flow restriction; inserting the flow restriction into the pipe; and thermally conditioning the flow restriction and/or the pipe such that the temperatures of the pipe and the flow restriction are equal, such that each of the plurality of centre portion projections of the flow restriction engages the inner surface of the pipe.

1. A flow restriction for being arranged in a pipe so as to restrict the flow of a fluid in the pipe, the flow restriction comprising:
a body extending along an axis, the body comprising:
a central portion having an essentially constant cross section along the axis;
an upstream portion connected to an upstream side of the central portion along the axis, wherein the cross-sectional area of the upstream portion monotonically increases in a downstream direction along the axis; and
a downstream portion connected to a downstream side of the central portion, wherein the cross-sectional area of the downstream portion monotonically decreases in the downstream direction; and
a plurality of central portion projections for engaging the inner surface of the pipe, wherein each central portion projection projects from the surface of the central portion in a direction perpendicular to the surface of the central portion by a distance of less than 500 μm.

2. The flow restriction of claim 1, wherein each central portion projection projects from the surface of the central portion in a direction perpendicular to the surface of the central portion by a distance of more than 10 μm.

3. The flow restriction of claim 1, wherein the body is essentially cylindrically symmetric about the axis,
the central portion comprises a cylinder, and
each of the plurality of projections projects in a direction perpendicular to the axis.

4. The flow restriction of claim 3, wherein the downstream portion comprises a cone with a cone angle in the range from 2° to 15°.

5. The flow restriction of claim 1, wherein the downstream portion comprises a cusped edge configured to direct a fluid flowing along the surface of the cusped edge in a direction parallel to the axis.

6. The flow restriction of claim 1, further comprising a flow splitting element that is configured to entirely surround the downstream portion of the body in a plane perpendicular to the axis,
wherein the flow splitting element is configured to be spaced apart from the downstream portion in a direction perpendicular to the axis such that the distance between the flow splitting element and the downstream portion monotonically increases in the downstream direction.

7. The flow restriction of claim 6, wherein the flow splitting element comprises a truncated hollow cone that is concentrically arranged around the downstream portion.

8. The flow restriction of claim 7, wherein the downstream portion comprises a cone and wherein the truncated hollow cone has a cone angle in the range from 0.3 to 0.7 times the cone angle of the cone of the downstream portion.

9. The flow restriction of claim 6, wherein the flow splitting element is shorter than the downstream portion in a direction along the axis.

10. The flow restriction of claim 6, wherein the flow splitting element comprises a plurality of flow splitting element projections for engaging the inner surface of the pipe,
wherein the distance between the axis and the end surfaces of the flow splitting element projections is equal to the distance between the axis and the end surfaces of the central portion projections.

11. A flow restriction assembly comprising:
the flow restriction of claim 1; and
a pipe, wherein:
the pipe comprises an inner pipe surface;
the body of the flow restriction is concentrically arranged within the pipe, such that the distance between the central portion of the body and the inner pipe surface is essentially uniform; and
each of the central portion projections of the flow restriction engages the inner pipe surface so as to hold the flow restriction in place with respect to the pipe, and such that the distance between the central portion of the body and the inner pipe surface is less than 500 μm.

12. The flow restriction assembly of claim 11, wherein the pipe and the body of the flow restriction are cylindrically symmetric.

13. The flow restriction assembly of claim 11, further comprising a flow splitting element of the flow restriction that entirely surrounds the downstream portion of the flow restriction in a plane perpendicular to the axis,
wherein the flow splitting element is spaced apart from the downstream portion in a direction perpendicular to the axis such that the distance between the flow splitting element and the downstream portion monotonically increases in the downstream direction.

14. A lithographic apparatus comprising the flow restriction assembly of claim 11.

15. A method of manufacturing the flow restriction of claim 1, the method comprising:
machining the body from a single precursor material;
providing holes with a diameter equal to a diameter of the central portion projections in the central portion;
inserting the central portion projections into the holes; and
machining the central portion projections such that all central portion projections extend by an essentially uniform distance from the surface of the central portion.

16. A method of manufacturing the flow restriction assembly of claim 11, the method comprising
thermally conditioning the flow restriction and/or the pipe such that the temperature of the pipe is higher than the temperature of the flow restriction;
inserting the flow restriction into the pipe; and
thermally conditioning the flow restriction and/or the pipe such that the temperatures of the pipe and the flow restriction are essentially equal, such that each of the plurality of central portion projections of the flow restriction engages the inner surface of the pipe.

17. The flow restriction assembly of claim 11, wherein each central portion projection projects from the surface of the central portion in a direction perpendicular to the surface of the central portion by a distance of more than 10 μm.

18. The flow restriction assembly of claim 11, wherein the downstream portion comprises a cone with a cone angle in the range from 2° to 15°.

19. The flow restriction assembly of claim 11, wherein the downstream portion comprises a cusped edge configured to direct a fluid flowing along the surface of the cusped edge in a direction parallel to the axis.

20. The flow restriction assembly of claim 13, wherein the flow splitting element is shorter than the downstream portion in a direction along the axis.
